(19) United States
(12) Patent Application Publication
(10) Pub. No.: US 2015/0050812 A1
(43) Pub. Date: Feb. 19, 2015

(54) WAFER-LESS AUTO CLEAN OF PROCESSING CHAMBER

(71) Applicant: GLOBALFOUNDRIES Inc., Grand Cayman (KY)

(72) Inventor: Elliot John Smith, Dresden (DE)

(73) Assignee: GLOBALFOUNDRIES Inc., Grand Cayman (KY)

(21) Appl. No.: 13/965,483

(22) Filed: Aug. 13, 2013

(51) Int. Cl. H01L 21/67; H01L 21/3065

(52) U.S. Cl. CPC H01L 21/67069; H01L 21/3065
USPC 438/706; 156/345.1; 134/1.1

(57) ABSTRACT

A method for cleaning a processing chamber, for example, a strip chamber, configured for processing a wafer is provided which includes the steps of introducing an oxygen-containing gas into the processing chamber, generating an oxygen plasma from the oxygen-containing gas in the processing chamber, establishing a pressure of the oxygen plasma in the processing chamber of at least 1 Torr and maintaining the pressure of at least 1 Torr for at least 40 seconds. A system is also provided including a strip chamber for receiving and stripping the wafer and including a gas inlet and plasma generator means, as well as a controller configured for performing, when no wafer is present in the strip chamber, controlling inflow of an oxygen-containing gas into the processing chamber through the gas inlet and controlling the plasma generator means to generate an oxygen plasma.

### BACKGROUND OF THE INVENTION

1. Field of the Invention

Generally, the present disclosure relates to the field of the manufacture of integrated circuits and semiconductor devices, and, more particularly, to the cleaning of a processing chamber, particularly used for stripping processes.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer.

Particularly, for transistor devices with very short channel lengths, for example, of some 50 nm or below, gate structures with high-k dielectric gate insulating layers and one or more metal layers functioning as a gate electrode have been provided that show improved operational characteristics as compared to conventional silicon dioxide/polysilicon gates. The high-k isolation layers may include or consist of tantalum oxide, hafnium oxide, titanium oxide or hafnium silicates, for example.

There are basically two well-known processing methods for forming a planar or 3D transistor with a high-k/metal gate structure: the so-called “gate last” or “replacement gate” technique and the so-called “gate first” technique. In the replacement gate technique, a so-called “dummy” or sacrificial gate structure is initially formed and remains in place as many process operations are performed to form the device, for example, the formation of doped source/drain regions, performing an anneal process to repair damage to the substrate caused by the ion implantation processes and to activate the implanted dopant materials. At some point in the process flow, the sacrificial gate structure is removed to define a gate cavity where the final high-k/metal gate structure for the device is formed. Using the “gate first” technique, on the other hand, involves forming a stack of layers of material across the substrate, wherein the stack of materials includes a high-k gate isolation layer, one or more metal layers, a layer of polysilicon, and a protective cap layer, for example, silicon nitride. One or more etching processes are performed to pattern the stack of materials to thereby define the basic gate structures for the transistor devices.

However, in the context of the high-k/metal gate technology for the manufacture of transistor devices in the art, problems arose after completion of the stripping process of wafers in a strip chamber. Yields were negatively affected by detachment of the high-k dielectrics and resulting fallen gates. Lifted patterns resulting in the detachment of already finished gates (falling gates) pose a severe problem, significantly reducing the overall yield.

The inventors of the present invention found that surprisingly the problem of fallen gates in the context of the manufacture of FETs in the framework of high-k/metal gate technologies has to be attributed to the cleaning of processing chambers, in particular, strip chambers.

In view of the situation described above, the present disclosure provides techniques for cleaning processing chambers effectively in order to provide for more robust production and avoid faulty products, in particular, fallen gates in the context of high-h/metal gate manufacturing of semiconductor devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method for cleaning (WAC) a processing chamber, for example, a strip chamber, configured for processing a wafer includes the steps of introducing an oxygen-containing gas into the processing chamber, generating an oxygen plasma from the oxygen-containing gas in the processing chamber, establishing a pressure of the oxygen plasma in the processing chamber of at least 1 Torr and maintaining the pressure of at least 1 Torr for at least 40 seconds. The above-mentioned steps are carried out when no wafer is present in the processing chambers, i.e., they represent steps of WAC. Due to the long duration and high pressure as compared to the art, very efficient cleaning can be achieved.

Moreover, a method for processing of a semiconductor wafer is provided including etching the wafer in an etch chamber, transferring the etched wafer from the etch chamber to a strip chamber, stripping the wafer in the strip chamber and cleaning the strip chamber by the above-mentioned method for cleaning a processing chamber (here, the strip chamber) before and/or after transferring the wafer from the etch chamber to the strip chamber.

In addition, a system configured for performing stripping processing of a semiconductor wafer is provided including a strip chamber for receiving and stripping the wafer, wherein the strip chamber includes a gas inlet and plasma generator means. The system, furthermore, includes a controller configured for controlling, when no wafer is present in the strip chamber, inflow of an oxygen-containing gas into the processing chamber through the gas inlet, the plasma generator means to generate an oxygen plasma from the oxygen-containing gas and the strip chamber to establish a pressure of the oxygen plasma in the processing chamber of at least 1 Torr and to maintain the pressure of at least 1 Torr for at least 40 seconds. The controller may be configured to perform the controlling steps by reading computer-readable instructions for performing the steps of the above-mentioned methods.

Furthermore, a system for processing a semiconductor wafer is provided, for example, for the manufacture of high-k/metal gate transistor devices on the wafer, including an etch chamber configured for etching the semiconductor wafer, in particular, for completely etching gate electrodes of transistor devices, the above-mentioned system and means for transferring the etched wafer from the etch chamber to the strip chamber.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a method for processing a lot of wafers in an etch chamber and a strip chamber according to the art;

FIG. 2 is a flow chart illustrating the inventive WAC of a strip chamber within the sequence of processing of wafers; and

FIG. 3 illustrates a method for processing lots of wafers in an etch chamber and a strip chamber according to an example of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc., and is readily applicable to a variety of devices, including, but not limited to, logic devices, memory devices, etc.

The present disclosure provides a method for cleaning a processing chamber, in particular a strip chamber, in the context of wafer processing. Particularly, a novel wafer-less auto clean (WAC) for a processing chamber, for example, a strip chamber, is provided that results in a reliable removal of contaminants, such as radicals and microscopic particles, that in the art caused damages in produced semiconductor devices, for example, fallen gates in densely packed transistor devices manufactured by high-k/metal gate technologies.

The continuing trend for smaller geometries for semiconductor devices makes it difficult to maintain the uniformity and accuracy of critical dimensions. It has become increasingly important that the environments inside the processing chambers, for example, an etch chamber and a strip chamber, be clean and consistent to ensure acceptable wafer-to-wafer variability of the critical dimensions. As is known in the art, many of the processes carried out within the semiconductor processing chambers leave deposits on the inner surfaces of the processing chamber. As these deposits accumulate over time, they can become a source of particulate contamination that is harmful to the substrates being processed. The build-up of deposits on the inner surfaces of the chamber causes an inconsistent environment which adversely impacts the processing operation being performed.

In order to alleviate problems caused by the contamination of processing chambers after completion of processing of batch (lot) of production wafers, wafer-less auto clean (WAC) in a processing chamber is performed. Conventionally, a composite WAC recipe for both silicon and carbon byproduct removal is used involving a specific mixture of separate etchant gases for silicon removal and for carbon removal. For this, WAC processes currently being run within processing chambers may rely on fluorine-containing plasmas, particularly, SF₆/O₂ recipes, for cleaning the inner surfaces of the residues from processing operations performed in the processing chamber. The WAC processes are run at low pressure, for example, of some 0.1 Torr or below 0.05 Torr.

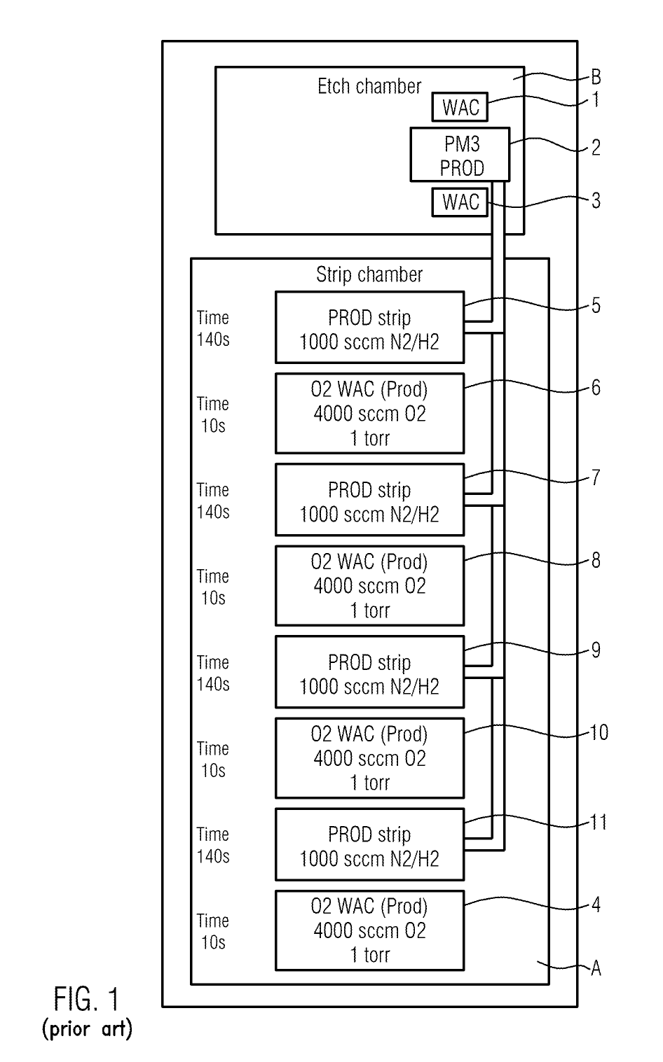

FIG. 1 shows an example of processing a lot of wafers in a strip chamber A and an etch chamber B. WAC is carried out 1 in the etch chamber B before loading a lot of wafers to be etched. In the etch chamber B, the loaded lot of wafers is subject to etching 2. After completion of the etching, the lot of wafers is transferred to the strip chamber A. Afterwards, WAC is carried out 3 in the etch chamber.

In the strip chamber A, an initial WAC is carried out 4 to lower the possibility of SiN buildup in SiO₂ parts of the wafers, for example. The lot of wafers received from the etch chamber B is subjected to stripping 5. After stripping is completed, the lot of wafers is transferred to a cooling chamber and a WAC is carried out 6 in the strip chamber A. The next lot of wafers etched in the etch chamber B is received and subjected to stripping 7. After stripping is completed, the lot of wafers is transferred to a cooling chamber and a WAC is carried out 8 in the strip chamber A. This processing is repeated in steps 9, 10 and 11. The stripping processes 5, 7, 9 and 11 may be performed for about 140 seconds on the basis of a conventional N₂/H₂ recipe provided with a flow rate of some 1000 sccm (standard cubic centimeters per minute), for example. The WAC processes 4, 6, 8 and 10 in the strip chamber A may typically be performed on the basis of O₂ at pressure conditions of less than 1 Torr at a flow rate of some 1000 sccm. Typically, the WAC processes 4, 6, 8 and 10 in the strip chamber A are performed for time periods of at most 10 seconds.

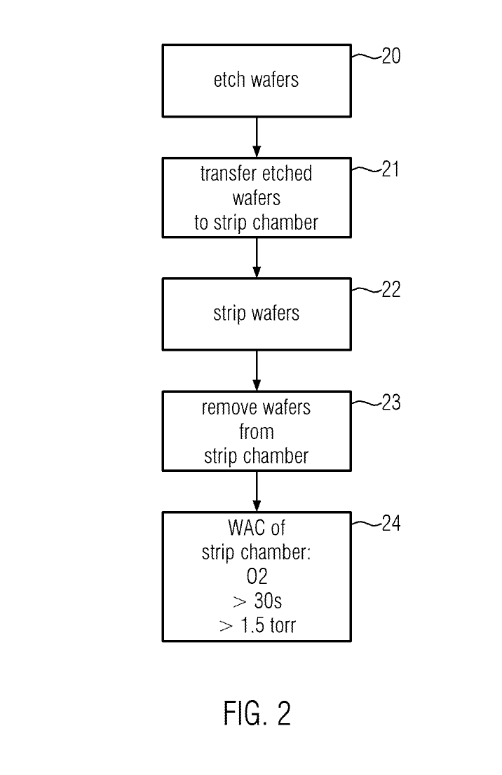

However, despite recent progress in cleaning the processing chambers from wall deposits by WAC, production yields still suffer from problems that are associated with radicals and microscopic particles being present in processing chambers as contaminants (for example, resulting from previously processed wafers or openings of the chamber). Extensive testing has proven that, in the framework of high-k/metal gate technologies used for the manufacture of FETs, the severe problem of lifted patterns resulting in the detachment of already finished gates (falling gates) is caused by insufficient cleaning of processing chambers, for example, strip chambers, rather than inaccurate wafer processing or material deficiencies. Therefore, an inventive WAC was designed by the inventors.

Whereas, in the art, WAC of processing chambers is well known, the inventive WAC presented herein is performed for significantly longer time periods and/or at significantly higher pressures as compared to the art. FIG. 2 illustrates an exemplary process flow for manufacturing wafers. Wafers comprising intermediate semiconductor devices are etched 20 in an etch chamber. Particularly, gates of transistor devices may be completely etched. After completion of the etching process, the wafers are transferred 21 to a strip chamber provided for final stripping 22 of the wafers. Particularly, the wafers may be de-fluorinated in the strip chamber based on an H₂/N₂ recipe as known in the art. After completion of the stripping process, the wafers are removed 23 from the strip chamber and, for example, transferred to a cooling station.

After removal of the stripped wafers, the strip chamber is subjected to a WAC 24 according to an example of the present invention. The WAC 24 is performed by an O₂ plasma at a pressure of at least 1 Torr (133.3 Pa) for a treatment time of more than 30 seconds, in particular, more than 40 seconds, more particularly, more than 50 seconds, and, even more particularly, at least 60 seconds. According to an example, the WAC was run for more than 30 seconds, in particular, more than 40 seconds, more particularly, more than 50 seconds, and, even more particularly, at least 60 seconds, at a pressure of at least 1.5 Torr, in particular, at least 2 Torr, and, more particularly, at least 2.5 Torr, and, even more particularly, at least 4 Torr. Higher pressures as compared to the art result in a higher density of the plasma and, thus, an improved cleaning of parts and walls of the processing chamber. The O₂ flow rate may be in the range of 500-5000 sccm, in particular, above 1000 sccm, more particularly, in the range of 3000-5000 sccm.

With the above parameters specifying the pressure provided by the strip chamber and the treatment time of the WAC carried out by O₂ plasma, the problem of fallen gates may be significantly alleviated and, thus, the yield may be increased. The combined higher pressure and longer treatment time as compared to the art results in significantly improved yields, particularly for high-k/metal gate technologies.

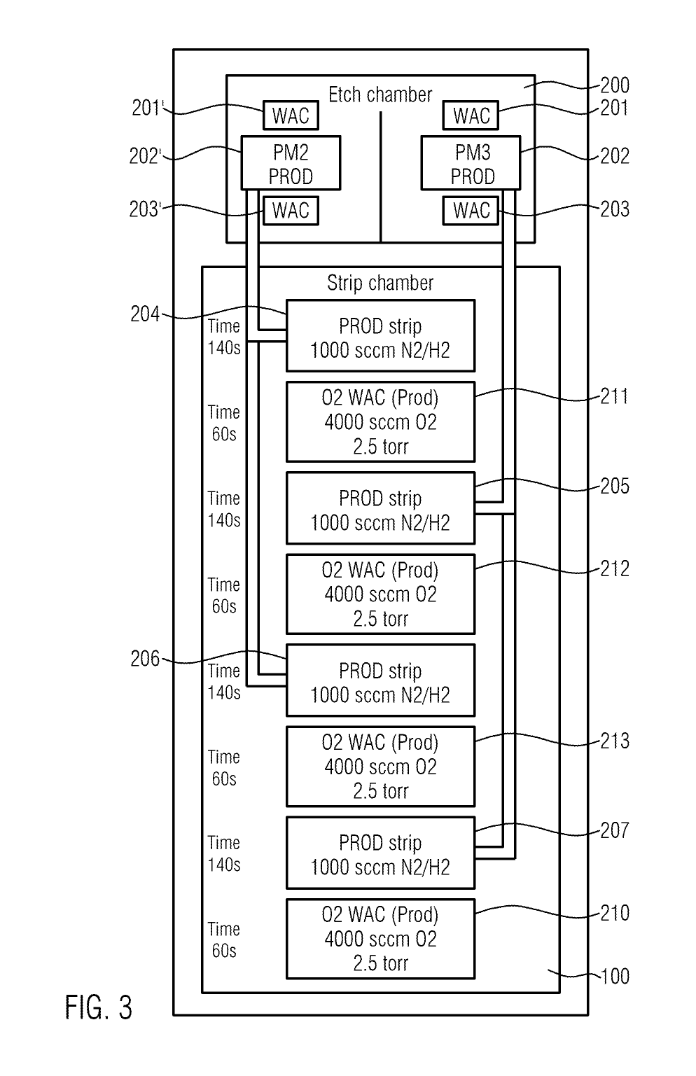

An exemplary process flow for wafer manufacturing including an example of the inventive WAC is illustrated in FIG. 3. The employed tool comprises a strip chamber 100 and two etch chambers 200. After an initial WAC 201, 201′ in each of the etch chambers 200, a lot of wafers (the lot may consist of one or more wafers, in principle) is etched 202, 202′, for example, in an F and CL rich etch plasma generated in each of the etch chambers 200. After removal of the lots of wafers, each of the etch chambers 200 is subjected to another WAC 203, 203′.

The wafers may be complete with several layers of materials and devices. For example, a wafer having a metal layer and a patterned photoresist and/or hardmask is placed into one of the plasma etch chambers 200. The etch process may contain several steps in which parameters of pressure, gas and power are combined in order to produce excited chemical species within the etch chamber. The excited chemical species of the etchant plasma may contain radicals, ions and neutrals which interact to varying degrees with exposed areas on the wafer, i.e., areas which are not covered and protected by the photoresist or the hardmask. The interaction of elements of the plasma with the exposed material of the substrate effectively removes material in the uncovered region. Removal of the wafers from one of the etch chambers 200 and placement in the strip chamber 100 may be accomplished by a cluster tool. The cluster tool configuration provides efficient automated movement of wafers between the processing chambers 200 and 100, for example.

Once a wafer is placed in the heated strip chamber 100, it is treated 204, 205, 206 and 207 with gases, for example, including oxygen, nitrogen and water vapor, in a pressure-controlled environment excited by a power source. Treatment in the strip chamber serves to remove the photoresist and/or hardmask as well as undesired materials remaining from the etch process. In one such application, water vapor and oxygen provide passivation of the chemical reaction between aluminum and etchant gasses from the previous etch process. Passivation, as used herein, describes a prevention of further chemical reaction of halogen-containing etchants, including chlorine and fluorine, that may otherwise cause corrosion of materials, including aluminum and aluminum copper alloys. According to an example, the wafer is de-fluorinated by H₂/N₂ in the strip chamber 100. Before usage, an initial WAC may be carried out 210 in the strip chamber 100 in order to reduce undesired SiN buildup on SiO₂ parts of the etched wafers, when stripping 204, 205, 206 and 207 is performed based on an H₂/N₂ recipe in the strip chamber 100.

For example, a wafer is transferred from one of the etch chambers 200 to the strip chamber 100 and subjected to stripping 204 for some 140 seconds. After stripping is completed, the wafer is removed and WAC is carried out 211 in the strip chamber 100. After completion of the WAC 211, another wafer is transferred from the other one of the etch chambers 200 to the strip chamber 100 and is subjected to stripping 205. After stripping is completed, the wafer is removed and WAC is carried out 212 in the strip chamber 100. After completion of the WAC 212, another wafer is transferred from one of the etch chambers 200 to the strip chamber 100 and it is subjected to stripping 206. After stripping is completed, the wafer is removed and WAC is carried out 213 in the strip chamber 100. Then, another wafer is transferred from the other one of the etch chambers 200 to the strip chamber 100 and is subjected to stripping 207. This sequence may be repeated according to the production plan designed for the overall process flow.

Conventionally, the WAC in the strip chamber was performed using an O₂ plasma at a pressure of below 1 Torr and the WAC was run for about 10 seconds, in particular, less than 20 seconds. In the described example, to the contrary, the WAC is performed by an O₂ plasma at a pressure of at least 1 Torr for a treatment time of more than 30 seconds, in particular, more than 40 seconds, more particularly, more than 50 seconds, and, even more particularly, at least 60 seconds. According to one example, the WAC was run for more than 30 seconds, in particular, more than 40 seconds, more particularly, more than 50 seconds. and, even more particularly, at least 60 seconds, at a pressure of at least 1.5 Torr, in particular, at least 2 Torr, and, more particularly, at least 2.5 Torr. In the context of high-k/metal gate technologies, satisfying results in terms of the overall yield were obtained, for example, for treatment times longer than 40 seconds at a pressure of the O₂ plasma of more than 1.5 Torr, in particular, more than 2 Torr, for example, for a treatment time of at least 45 seconds, more particularly, more than 60 seconds. The O₂ flow rate may be in the range of 500-5000 sccm, in particular, above 1000 sccm, more particularly, in the range of 3000-5000 sccm.

In all of the above-described examples, the pressure in the strip chamber may be controlled independently of the flow rate by means of a conductance meter. In all of the above-described examples, the O₂ plasma used for the WAC of the strip chamber may contain more than 50% O₂, in particular, more than 90% O₂. The plasma may be generated, for example, by a transformer coupled plasma coil providing 800-3000 Watts. The temperature of the chamber may be in the range of 20-300° C., for example. Even higher temperatures may be involved.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for cleaning a processing chamber configured for processing a wafer, comprising the steps of:
introducing an oxygen-containing gas into said processing chamber;
generating an oxygen plasma from said oxygen-containing gas in said processing chamber;
establishing a pressure of said oxygen plasma in said processing chamber of at least 1 Torr; and
maintaining said pressure of at least 1 Torr for at least 40 seconds.

2. The method of claim 1, wherein said pressure is maintained for at least 50 seconds or at least 60 seconds.

3. The method of claim 1, wherein said pressure of said oxygen plasma is at least 2 Torr.

4. The method of claim 1, wherein said oxygen-containing gas comprises at least 50-90% O₂.

5. The method of claim 1, wherein said oxygen-containing gas is introduced with a flow rate of at least 2000-4000 sccm.

6. The method of claim 1, wherein said processing chamber is a strip chamber configured for strip processing of wafers.

7. The method of claim 1, wherein, prior to introducing said oxygen-containing gas into said process chamber, the method further comprises:
etching said wafer in an etch chamber;
transferring the etched wafer from said etch chamber to said process chamber; and
stripping said etched wafer in said process chamber.

8. The method of claim 7, wherein etching said wafer comprises etching a plurality of gates of a plurality of transistor devices.

9. The method of claim 7, wherein stripping said etched wafer comprises defluorinating said etched wafer based on an H₂/N₂ recipe.

10. A system configured for performing stripping processing of a semiconductor wafer, comprising:
a strip chamber for receiving and stripping said semiconductor wafer, said strip chamber comprising a gas inlet and plasma generator means; and
a controller configured for performing when no wafer is present in said strip chamber:
controlling inflow of an oxygen-containing gas into said strip chamber through said gas inlet;
controlling said plasma generator means to generate an oxygen plasma from said oxygen-containing gas; and
controlling said strip chamber to establish a pressure of said oxygen plasma in said strip chamber of at least 1 Torr and to maintain said pressure of at least 1 Torr for at least 40 seconds.

11. The system of claim 10, wherein said controller is configured to control said strip chamber to maintain said pressure for at least 60 seconds.

12. The system of claim 10, wherein said controller is configured to control said strip chamber to maintain said pressure at at least 2 Torr.
